(19) United States
(12) Patent Application Publication
(10) Pub. No.: US 2025/0275461 A1
(43) Pub. Date: Aug. 28, 2025

(54) IRIDIUM COMPLEX AND ORGANIC ELECTROLUMINESCENT DEVICE COMPRISING SAME

(71) Applicant: Korea University Research and Business Foundation, Sejong Campus, Sejong (KR)

(72) Inventors: Sangook Kang, Sejong (KR); Hojin Son, Sejong (KR)

(21) Appl. No.: 18/549,843

(22) PCT Filed: Mar. 8, 2022
(86) PCT No.: PCT/KR2022/003310

§ 371 Date: Feb. 21, 2024

(30) Foreign Application Priority Data
Mar. 8, 2021 (KR) 10-2021-0030439
Mar. 8, 2022 (KR) 10-2022-0029089

(51) Int. Cl. H10K 85/30; C07F 15/00; C09K 11/06; H10K 50/12

(52) U.S. Cl. CPC H10K 85/342; C07F 15/0033; C09K 11/06; C09K 2211/1044; C09K 2211/1092; C09K 2211/185; H10K 50/12

(57) ABSTRACT

The present invention relates to a novel iridium complex and an organic electroluminescent device comprising same and, specifically, to a novel iridium complex that can be used as a blue phosphorescent dopant of a light-emitting layer and an organic electroluminescent device comprising same.

### TECHNICAL FIELD

The present disclosure relates to a novel iridium complex and an organic electroluminescent device including same and, more specifically, to a novel iridium complex that can be used as a blue phosphorescent dopant in a light-emitting layer and an organic electroluminescent device including same.

### BACKGROUND ART

Recently, efforts have been made to enhance the luminous efficiency of phosphorescent organic light-emitting diodes (PhOLEDs). As a result, a technology that exhibits a high external quantum efficiency of 29% for green and 15% for red has been reported. However, blue phosphorescent organic light-emitting diodes are reported to have lower luminous efficiency, color coordinate characteristics, and lifespan compared to green and red phosphorescent organic light-emitting diodes. To address this, extensive research is being conducted, mainly focusing on improving the layer structure of the diodes and studying new hosts and dopants. For instance, Korean Patent No. 10-2010-0061831 A discloses a technology related to metal complex compounds as blue phosphorescent dopants.

However, when the dopant performance according to conventional techniques, namely, the conventional metal complex compounds used as blue phosphorescent materials, is applied as a dopant to a light-emitting layer, improvements in color coordinates are required. Furthermore, there are issues such as decreased efficiency of the dopant and non-luminous processes easily occurring due to excitons, leading to deterioration of diode stability. Moreover, blue phosphorescent dopants are the most essential materials sought after in the current display industry. Still, there is no known material that secures efficiency and lifespan while closely approaching the color coordinates of [0.15, 0.10].

### DISCLOSURE OF INVENTION

### Technical Problem

The present disclosure aims to provide a novel iridium complex that can be used as a dopant in the light-emitting layer of organic electroluminescent devices, especially as a deep blue phosphorescent dopant with excellent luminescent properties and ability to realize deep blue phosphorescence.

Also, the present disclosure is to provide an organic electroluminescent device that includes the novel iridium complex and emits blue phosphorescence.

### Solution to Problem

In accordance with an aspect thereof, the present disclosure provides an iridium complex represented by the following Chemical Formula 1:

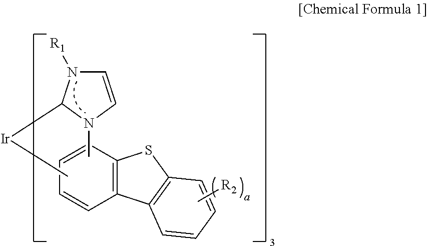

(wherein,
R₁ is an alkyl of C₁-C₂₀,
a is an integer of 0 to 4,
R₂ is selected from the group consisting of a hydrogen atom, a deuterium atom, a halogen, a cyano, an alkyl of C₁-C₂₀, an alkenyl of C₂-C₄₀, an alkynyl of C₂-C₂₀, a cycloalkyl of C₃-C₂₀, a heterocycloalkyl of 3 to 20 nuclear atoms, an aryl of C₆-C₂₀, a heteroaryl of 5 to 20 nuclear atoms, an alkyloxy of C₁-C₂₀, and an aryloxy of C₆-C₂₀).

In accordance with another aspect thereof, the present disclosure provides an electroluminescent device, including: a first electrode; a second electrode; and a light-emitting layer disposed between the first electrode and the second electrode, wherein the light-emitting layer includes the iridium complex represented by Chemical Formula 1.

### Advantageous Effects of Invention

Exhibiting excellent luminescent characteristics and ability to achieve deep blue phosphorescence, the iridium complex according to the present disclosure can be used as an organic material layer in organic electroluminescent devices. Specifically, when used as a dopant in the light-emitting layer, especially as a blue phosphorescent dopant, the iridium complex of the present disclosure allows for the production of blue phosphorescent light-emitting devices with superior luminescence performance, lower driving voltage, higher efficiency, and longer lifespan compared to conventional materials. Moreover, it can also lead to the production of full-color display panels with enhanced performance and lifespan.

### BRIEF DESCRIPTION OF DRAWINGS

FIG. 1 is a schematic cross-sectional view of an electroluminescent device according to a first embodiment of the present disclosure.

FIG. 2 is a schematic cross-sectional view of an electroluminescent device according to a second embodiment of the present disclosure.

FIG. 3 is a schematic cross-sectional view of an electroluminescent device according to a third embodiment of the present disclosure.

FIG. 4 shows models of molecule accounting for single crystal structures of f-IrS^{iPr} and m-IrS^{iPr} synthesized in Synthesis Example 2, with hydrogen atoms omitted for clarity.

FIG. 5 shows absorption spectra of m-IrS^{Me} of Synthesis Example 1, f-IrS^{iPr} and m-IrS^{iPr} of Synthesis Example 2, f-IrO^{Me} of Comparative Example 1, and m-IrO^{Me} of Comparative Example 2 in CH₂Cl₂ at 300 K.

FIG. 6(a) shows phosphorescence emission spectra of m-IrS^{Me} of Synthesis Example 1, f-IrS^{iPr} and m-IrS^{iPr} of Synthesis Example 2, f-IrO^{Me} of Comparative Example 1, and m-IrO^{Me} of Comparative Example 2 in CH₂Cl₂ at 300 K and FIG. 6(b) shows phosphorescence emission spectra of m-IrS^{Me} of Synthesis Example 1, f-IrS^{iPr} and m-IrS^{iPr} of Synthesis Example 2, f-IrO^{Me} of Comparative Example 1, and m-IrO^{Me} of Comparative Example 2 in 2-MeTHF at 77 K (λₑₓ=355 nm).

FIG. 7 shows cyclic voltammograms of m-IrS^{Me} of Synthesis Example 1, f-IrS^{iPr} and m-IrS^{iPr} of Synthesis Example 2, f-IrO^{Me} of Comparative Example 1, and m-IrO^{Me} of Comparative Example 2.

FIG. 8 shows frontier molecular orbitals of m-IrS^{Me} of Synthesis Example 1, f-IrS^{iPr} and m-IrS^{iPr} of Synthesis Example 2, f-IrO^{Me} of Comparative Example 1, and m-IrO^{Me} of Comparative Example 2.

FIG. 9 is a schematic view of the device structures of Examples 1 and 2 and Comparative Examples 1 and 2.

FIG. 10 shows performance of the devices of Examples 1 and 2 and Comparative Examples 1 and 2 in terms of J-V-L characteristics (a), current efficiency-current density-power efficiency (b), external quantum efficiency (c), and electroluminescence spectra (d).

FIG. 11 is a plot of external quantum efficiencies of devices of Example 2 and Comparative Examples 1-2, with a CIE coordinate plot inserted therein.

** Description of Reference Numerals **

| | |
|---|---|
| 100: anode, | 200: cathode, |
| 300: organic layer, | 310: hole injection layer, |
| 320: hole transport layer, | 330: light-emitting layer, |
| 340: electron transport layer, | 350: electron injection layer, |
| 360: electron transport auxiliary layer | |

### BEST MODE FOR CARRYING OUT THE INVENTION

Below, a detailed description will be given of the present disclosure.

### <Novel Iridium Complex>

The present disclosure concerns a homoleptic cyclometalated iridium complex having the basic structure, represented by Chemical Formula 1, where an N-heterocyclic carbene-dibenzothiophene ligand (NHC-dibenzothiophene ligand) is arranged around the hexa-coordinated iridium and an alkyl radical is bonded (introduced) to the N-heterocyclic carbene moiety within the ligand. The iridium complex represented by Chemical Formula 1, according to the present disclosure, not only exhibits excellent luminescent characteristics but can also achieve deep blue phosphorescence and as such, can be used a dopant for the light-emitting layer of organic electroluminescent devices, especially as a deep blue phosphorescent dopant.

Specifically, the iridium complex denoted by chemical formula 1 is in a chelate form and forms a hexa-coordination solely with homogenous NHC-dibenzothiophene ligands. In this way, the iridium complex of Chemical Formula 1 that forms a hexa-coordination with homogeneous ligands alone can achieve deep blue phosphorescence with CIE coordinates close to (0.15, 0.10), as compared to heteroleptic Ir complexes that form hexa-coordination with different ligands.

Moreover, the dibenzothiophene moiety of the NHC-dibenzothiophene ligand in the iridium complex represented by Chemical Formula 1 has a stronger electronegativity than a dibenzofuran moiety, resulting in a broader T1-S0 energy gap and a shorter emission wavelength compared to dibenzofuran-based complexes.

The iridium complex, represented by chemical formula 1, in which an alkyl group is introduced to the N-heterocyclic carbene moiety of the NHC-dibenzothiophene ligand exhibits increased stability and enhanced deep blue color coordinates. The introduction of an alkyl group to the N-heterocyclic carbene moiety decreases the thermal degradation attributed to long-term operation of OLEDs, without degrading the luminescent characteristics, thus improving lifespan characteristics of the OLEDs. Furthermore, when only an alkyl group is introduced to the N-heterocyclic carbene moiety as in the present invention, the blue luminescent characteristics can be improved compared to the case where other functional groups (e.g., phenyl groups) are introduced together.

Additionally, if the iridium complex represented by Chemical Formula 1 is a meridional isomer, the meridional isomer possesses a mutual trans-phenyl ligand configuration, which can elongate the transoid Ir—C bond length and destabilize the HOMO level. Such an iridium complex of Chemical Formula 1 is more likely to undergo oxidation and allows luminescence to exhibit red-shifting, compared to facial forms.

Moreover, the iridium complex represented by Chemical Formula 1 can achieve deep blue phosphorescence even at low temperatures or in solid-state film luminescence.

As mentioned above, the iridium complex as per the present disclosure, represented by Chemical Formula 1, not only has excellent luminescence characteristics but can also achieve blue phosphorescence, especially with color coordinates close to [0.15, 0.10]. Thus, the compound of the present disclosure can be used in the organic layer of organic electroluminescent devices, specifically as a dopant in the light-emitting layer, and in particular, as a blue phosphorescent dopant. When applied as a dopant in the light-emitting layer of an organic electroluminescent device, the compound iridium complex, represented by Chemical Formula 1 of the present disclosure, guarantees superb luminescent characteristics and can realize blue phosphorescence. Accordingly, the iridium complex can be used as a material for the organic layer of organic electroluminescent devices. In particular, when used as a dopant in the light-emitting layer, especially as a blue phosphorescent dopant, the iridium complex allows for the fabrication of blue phosphorescent light-emitting diodes with better luminescence performance, lower driving voltage, higher efficiency, and longer lifespan compared to conventional diodes, and can be further applied to full-color display panels with improved performance and lifespan.

In the iridium complex represented by Chemical Formula 1, R₁ is an alkyl of C₁-C₂₀ and specifically an alkyl of C₁-C₁₀. According to an embodiment, R₁ may be selected from the group consisting of methyl, ethyl, n-propyl, iso-propyl, n-butyl, iso-butyl or sec-butyl, and tert-butyl.

In the iridium complex represented by Chemical Formula 1, a is an integer of 0 to 4 and specifically 0 or 1. The case where a is 0 means that any of the hydrogen atoms are not substituted by the substituents R₂. When a is an integer of 1 or 4, one to four of the hydrogen atoms are substituted by the substituent R₂. In this regard, the multiple R₂'s are same or different and are each independently selected from the group consisting of a deuterium atom, a halogen, a cyano, an alkyl of C₁-C₂₀, an alkenyl of C₂-C₄₀, an alkynyl of C₂-C₂₀, a cycloalkyl of C₃-C₂₀, a heterocycloalkyl of 3 to 20 nuclear atoms, an aryl of an aryl of C₆-C₂₀, a heteroaryl of 5 to 20 nuclear atoms, an alkyloxy of C₁-C₂₀, and an aryloxy of C₆-C₂₀ and specifically from the group consisting of a deuterium atom, a halogen, a cyano, an alkyl of C₁-C₂₀, an aryl of C₆-C₂₀, and a heteroaryl of 5 to 20 nuclear atoms.

The iridium complex represented by Chemical Formula 1 may be an iridium complex represented by Chemical Formula 2, but is not limited thereto:

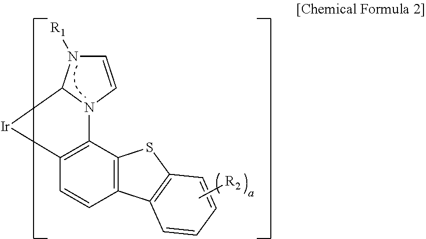

wherein,
R₁, R₂, and a are defined as in Chemical Formula 1.

In detail, the iridium complex represented by Chemical Formula 1 may be an iridium complex represented by any one of the following Chemical Formulas 3 to 5, but is not limited thereto:

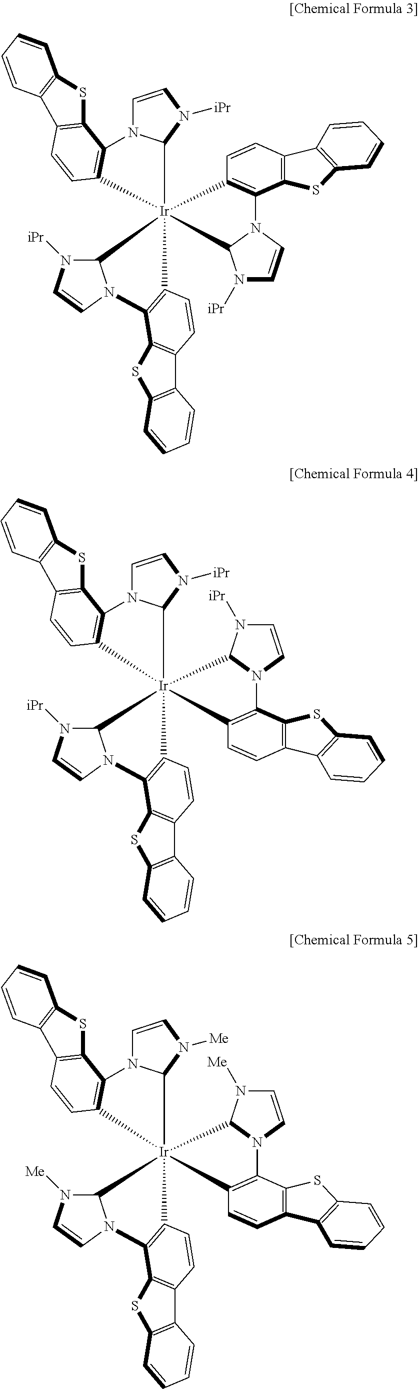

wherein,
iPr stands for isopropyl and Me stands for methyl.

As used herein, “alkyl” refers to a monovalent substituent derived from a saturated, linear or branched hydrocarbon of 1 to 20 carbon atoms. Examples of such alkyl may include, but are not limited to, methyl, ethyl, propyl, isobutyl, sec-butyl, pentyl, iso-amyl, hexyl, or the like.

As used herein, “alkenyl” refers to a monovalent substituent derived from an unsaturated, linear or branched hydrocarbon of 2 to 20 carbon atoms, with at least one carbon-carbon double bond therein. Examples of such alkenyl may include, but are not limited to, vinyl, allyl, isopropenyl, 2-butenyl, or the like.

As used herein, “alkynyl” refers to a monovalent substituent derived from an unsaturated, linear or branched hydrocarbon of 2 to 20 carbon atoms, with at least one carbon-carbon triple bond therein. Examples of such alkynyl may include, but are not limited to, ethynyl, 2-propynyl, or the like.

As used herein, “cycloalkyl” refers to a monovalent substituent derived from a monocyclic or polycyclic non-aromatic hydrocarbon having 3 to 20 carbon atoms. Examples of such cycloalkyl may include, but are not limited to, cyclopropyl, cyclopentyl, cyclohexyl, norbornyl, adamantine, or the like.

As used herein, “heterocycloalkyl” refers to a monovalent substituent derived from a non-aromatic hydrocarbon having 3 to 20 nuclear atoms, where one or more carbons in the ring, preferably one to three carbons, are substituted with a heteroatom such as N, O, S or Se. Examples of such heterocycloalkyl may include, but are not limited to, morpholine, piperazine, or the like.

As used herein, “aryl” refers to a monovalent substituent derived from an aromatic hydrocarbon of 6 to 20 carbon atoms having a single ring or two or more rings combined with each other. In addition, a form in which two or more rings are simply attached (pendant) to or condensed with each other may also be included. Examples of such aryl may include, but are not limited to, phenyl, naphthyl, phenanthryl, anthryl, or the like.

As used herein, “heteroaryl” refers to a monovalent substituent derived from a monoheterocyclic or polyheterocyclic aromatic hydrocarbon having 5 to 20 nuclear atoms. In this regard, one or more carbons in the ring, preferably one to three carbons, are substituted with a heteroatom such as N, O, S, or Se. In addition, a form in which two or more rings are pendant to or condensed with each other may be included, and a form condensed with an aryl group may be included. Examples of such heteroaryl may include, but are not limited to, a 6-membered monocyclic ring such as pyridyl, pyrazinyl, pyrimidinyl, pyridazinyl and triazinyl; a polycyclic ring such as phenoxathienyl, indolizinyl, indolyl, purinyl, quinolyl, benzothiazole and carbazolyl; 2-furanyl; N-imidazolyl; 2-isoxazolyl; 2-pyridinyl; 2-pyrimidinyl, or the like.

As used herein, “alkyloxy” refers to a monovalent substituent represented by R′O—, where R′ is an alkyl having 1 to 20 carbon atoms. Such alkyloxy may include a linear, branched or cyclic structure. Examples of such alkyloxy may include, but are not limited to, methoxy, ethoxy, n-propoxy, 1-propoxy, t-butoxy, n-butoxy, pentoxy, or the like.

As used herein, “aryloxy” refers to a monovalent substituent represented by RO—, where R is an aryl having 6 to 20 carbon atoms. Examples of such aryloxy may include, but are not limited to, phenyloxy, naphthyloxy, diphenyloxy, or the like.

### <Organic Electroluminescence Device>

Also, the present disclosure provides an organic electroluminescent device, specifically a blue phosphorescent organic electroluminescent device including the iridium complex represented by Chemical Formula 1.

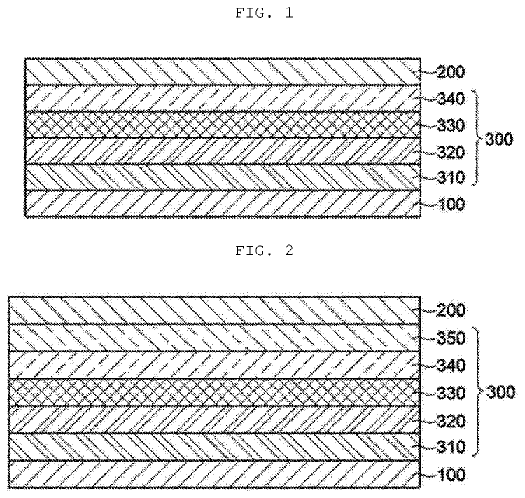

As shown in FIGS. 1 to 3, the phosphorescent organic electroluminescent device according to the present disclosure includes an anode (100), a cathode (200), and at least one organic layer (300) disposed between the anode and the cathode, wherein the at least one organic layer contains the iridium complex represented by Chemical Formula 1. In this regard, the iridium complexes may be used alone or in combination with each other.

The at least one organic layer (300) may include at least one of a hole injection layer (310), a hole transport layer (320), a light-emitting layer (330), an electron transport layer (340), and an electron injection layer (350) and optionally further include an electron transport auxiliary layer (360). In this regard, the at least one organic layer (300) includes an iridium complex represented by Chemical Formula 1. Specifically, the organic layer including the iridium complex of Chemical Formula 1 may be the light-emitting layer (330).

According to an embodiment, the at least one organic layer may include a hole injection layer, a hole transport layer, a light-emitting layer, an electron transport layer, and an electron injection layer and may optionally further include an electron transport auxiliary layer, wherein the light-emitting layer contains a host and a dopant and the dopant (specifically, blue phosphorescent dopant) being an iridium complex represented by Chemical Formula 1. When the iridium complex represented by Chemical Formula 1 is incorporated in small amounts into the light-emitting layer of a phosphorescent organic electroluminescent device, the excitons generated in the light-emitting layer material, that is, the host material, can be transferred to the dopant to reduce the driving voltage and increase the luminous efficiency, with the consequent improvement of lifespan, brightness, power efficiency, and thermal stability in the phosphorescent device.

The content of the iridium complex is not particularly limited. However, when the iridium complex is used in an amount of approximately 1-30 weight % based on the total amount of the light-emitting layer, the color purity and efficiency of light can be increased, leading to further enhancement in the luminous efficiency and lifespan characteristics of the device.

So long as it is typically known in the art, any host, particularly, blue phosphorescent host may be used in the present disclosure, without limitations. For example, a blue phosphorescent host may be selected from a group consisting of phosphine oxide compounds, carbazole compounds, silane compounds, and spirobifluorene compounds.

Specifically, examples of the host include 4,4′-bis(carbazol-9-yl)-2,2′dimethylbiphenyl (CDBP), 4,4′-N,N-dicarbazolebiphenyl (CBP), 1,3-N,N-dicarbazolebenzene (mCP), MCBP (9,9′,9″-(4,4′,4″-(methylsilanetriyl)tris(benzene-4,1-diyl))tris (9H-carbazole)), and derivatives thereof. Examples of the host include (4,4′bis(2,2-diphenyl-ethen-1-yl)diphenyl (DPVBi), bis(styryl)amine (DSA), bis(2-methyl-8-quinolinolato) (triphenylsiloxy)aluminum (III) (SAlq), bis(2-methyl-8-quinolinolato) (para-phenolato)aluminum (III) (BAlq), 3-(biphenyl-4-yl)-5-(4-dimethylamino)4-(4-ethylphenyl)-1,2,4-triazole (p-EtTAZ), 3-(4-biphenyl)-4-phenyl-5-(4-tert-butylphenyl)-1,2,4-triazole (TAZ), 2,2′,7,7′-tetrakis(biphenyl-4-yl)-9,9′-spirofluorene (Spiro-DPVBI), tris(para-tert-phenyl-4-yl)amine (p-TTA), 5,5-bis(dimesitylboryl)-2,2-bithiophene (BMB-2T), and perylene.

Further concrete examples of the blue phosphorescent host include, but are not limited to, TSPO1 (diphenyl-4-triphenylsilylphenylphosphine oxide), CBP-CN, mCP, mCPPO1, DCPPO, 26mCPy, PPO2, PPO27, mCBP, CzBPCb, CbBPCb, UGH1, UGH2, UGH3, BSB, SiCa, SimCP, SimCP2, TCTP, 26DCzPPy, 35DCzPPy, DBFCb, SPPO1, SPPO13, SF2BCz, and SF3 BC z.

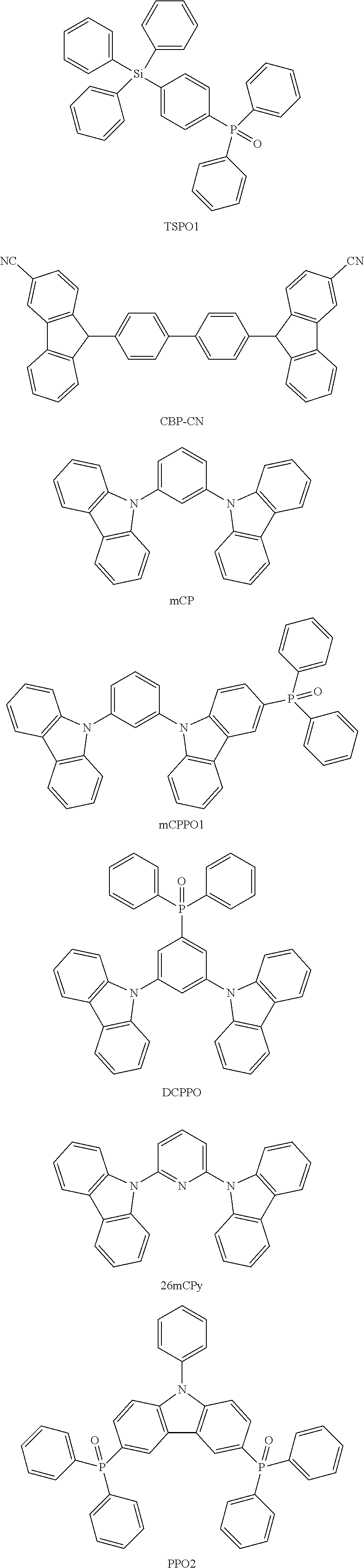

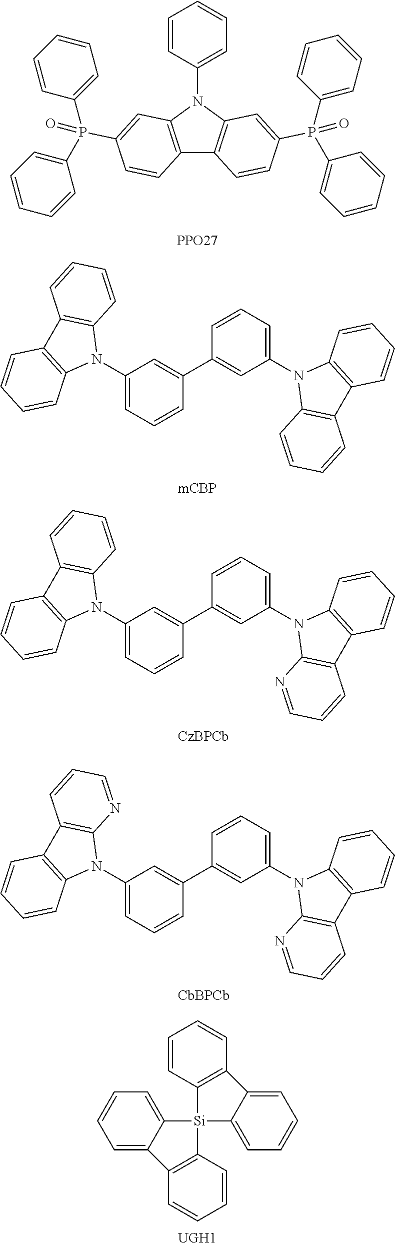 [SMILES: "PPO27" ; c1cc(-c2cccc(-n3c4ccccc4c4ccccc43)c2)cc(-n2c3ccccc3c3ccccc32)c1 ; O=P(c1ccccc1)(c1ccccc1)c1ccc2c3ccc(P(=O)(c4ccccc4)c4ccccc4)cc3n(-c3ccccc3)c2c1 ; c1cc(-c2cccc(-n3c4ccccc4c4cccnc43)c2)cc(-n2c3ccccc3c3ccccc32)c1 ; c1cc(-c2cccc(-n3c4ccccc4c4cccnc43)c2)cc(-n2c3ccccc3c3cccnc32)c1 ; c1ccc2c(c1)-c1ccccc1[Si]21c2ccccc2-c2ccccc21]

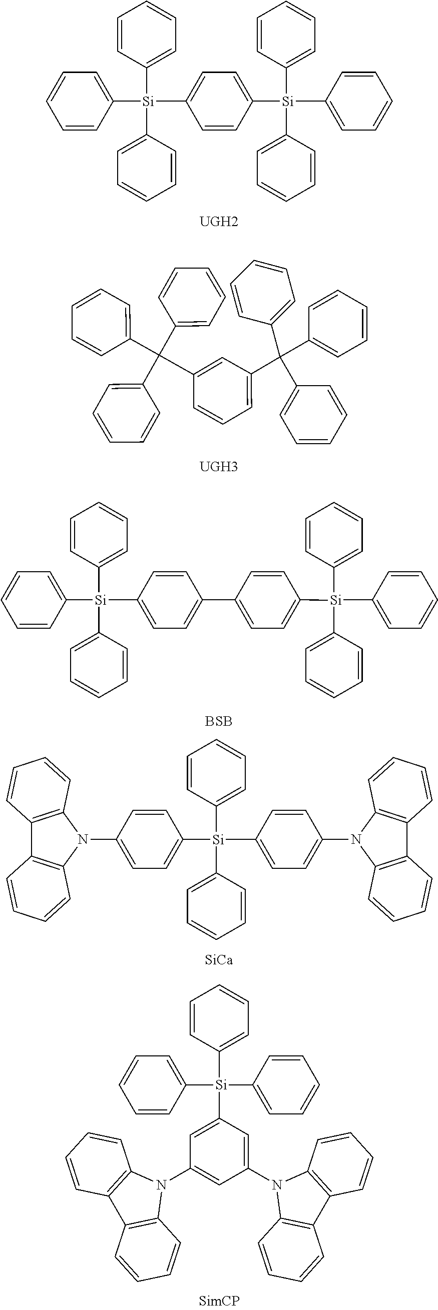

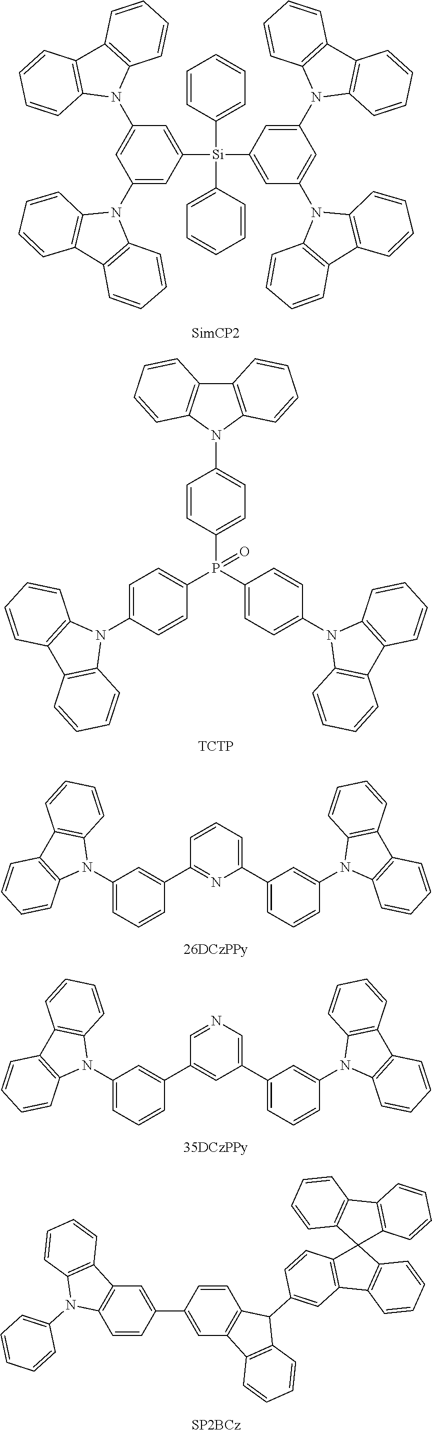 [SMILES: c1ccc([Si](c2ccccc2)(c2cc(-n3c4ccccc4c4ccccc43)cc(-n3c4ccccc4c4ccccc43)c2)c2cc(-n3c4ccccc4c4ccccc43)cc(-n3c4ccccc4c4ccccc43)c2)cc1 ; O=P(c1ccc(-n2c3ccccc3c3ccccc32)cc1)(c1ccc(-n2c3ccccc3c3ccccc32)cc1)c1ccc(-n2c3ccccc3c3ccccc32)cc1 ; "TCTP" ; c1cc(-c2cccc(-c3cccc(-n4c5ccccc5c5ccccc54)c3)n2)cc(-n2c3ccccc3c3ccccc32)c1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)-c4ccccc4C5c4ccc5c(c4)-c4ccccc4C54c5ccccc5-c5ccccc54)ccc32)cc1]

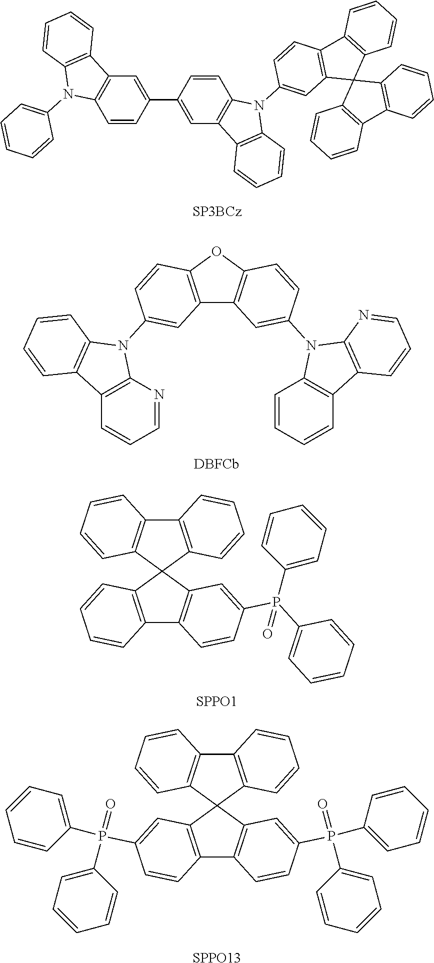

The host may be used in an amount of approximately 70-99% by weight based on the total weight of the light-emitting layer.

The structure of the organic electroluminescent device described in the present disclosure is not specifically limited. For example, an anode (100), at least one organic layer (300), and a cathode (200) can be sequentially laminated on a substrate (see FIGS. 1 to 3). Additionally, the organic electroluminescent device has the structure in which an insulating layer or adhesive layer, although not shown, is inserted at the interface between the electrode and the organic layers.

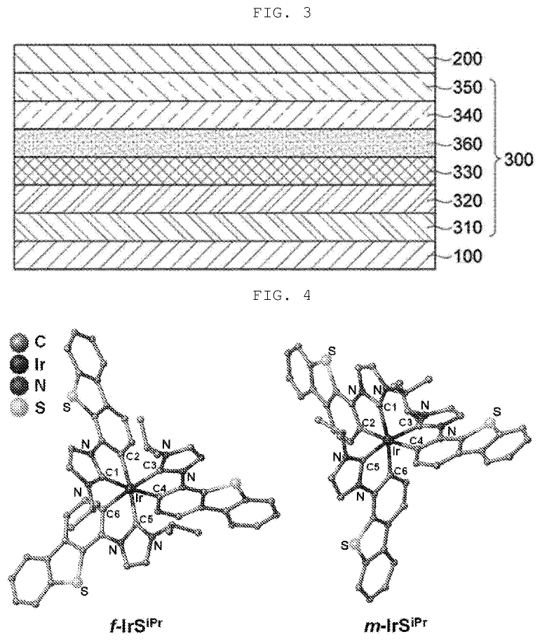

For instance, the organic electroluminescent device can have a structure, as depicted in FIG. 1, where an anode (100), a hole injection layer (310), a hole transport layer (320), a light-emitting layer (330), an electron transport layer (340), and a cathode (200) are successively stacked on the substrate. Optionally, as shown in FIG. 2, an electron injection layer (350) may be disposed between the electron transport layer (340) and the cathode (200). Furthermore, an electron transport auxiliary layer (360) may be disposed between the light-emitting layer (330) and the electron transport layer (340) (see FIG. 3).

Excluding that the at least one organic layer (300) [e.g., electron transport layer (340)] contains the compound represented by Chemical Formula 1, the organic electroluminescent device of the present invention can be fabricated by forming the organic layer and electrodes with materials and methods known in the technical field.

The organic layer may be formed by vacuum deposition or solution coating methods. Examples of the solution coating method include spin coating, dip coating, doctor blading, inkjet printing, and thermal transfer, but are not limited thereto.

The substrate usable in the present disclosure is not specifically limited. Non-limiting examples include silicon wafers, quartz, glass plates, metal plates, plastic films, and sheets.

Furthermore, examples of anode materials include: metals such as vanadium, chromium, copper, zinc, and gold or their alloys; metal oxides such as zinc oxide, indium oxide, indium tin oxide (ITO), and indium zinc oxide (IZO); combinations of metals and oxides such as ZnO:Al or SnO2:Sb; conductive polymers such as polythiophene, poly(3-methylthiophene), poly[3,4-(ethylene-1,2-dioxy)thiophene](PEDT), polypyrrole, or polyaniline; and carbon black, but are not limited thereto.

Moreover, examples of cathode materials include, but are not limited to, metals such like magnesium, calcium, sodium, potassium, titanium, indium, yttrium, lithium, gadolinium, aluminum, silver (Ag), tin, or lead, or alloys thereof; and multilayered materials such as LiF/Al or LiO₂/Al.

Additionally, the hole injection layer, hole transport layer, and electron injection layer are not particularly limited and may employ commonly known materials in the art.

A better understanding of the present disclosure may be obtained through the following examples which are set forth to illustrate, but are not to be construed to limit the present disclosure.

### [PREPARATION EXAMPLES]—Synthesis of Ligand

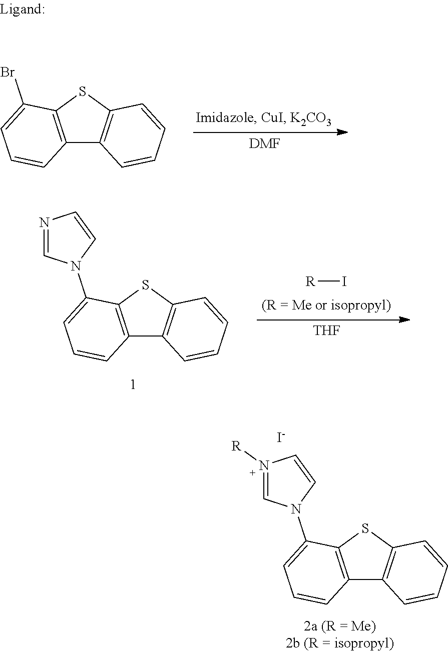

### [PREPARATION EXAMPLE 1] Synthesis of 1-(Dibenzo[b,d]thiophen-4-yl)-1H-imidazole (Compound 1)

4-Bromodibenzo-[b,d]thiophene (10.0 g, 38.0 mmol) was dissolved in dry dimethylformamide (200 mL). Imidazole (3.62 g, 53.2 mmol), copper(I) iodide (1.31 g, 6.88 mmol), and K₂CO₃ (6.83 g, 49.4 mmol) were added to the solution. This mixture was heated to 150° C., stirred for 48 hours, and then cooled to room temperature. Insoluble residues were filtered out. The solvent was removed from the filtrate and the residue was dissolved in CH₂Cl₂ (300 mL) to which a 25% NH₃ solution (30.0 mL) and water (400 mL) were added. Extraction through a separatory funnel isolated the organic phase. This organic phase was dried over MgSO₄ and filtered. The filtrate was dried to afford the target compound which was then used for subsequent reactions (Preparation Examples 2 and 3), without further purification.

### [PREPARATION EXAMPLE 2] Synthesis of 1-(Dibenzo[b,d]thiophen-4-yl)-3-methyl-1H-imidazol-3-ium iodide (Compound 2a)

To a solution of Compound 1 (8.4 g, 33.6 mmol) of Preparation Example 1 in THF (120 mL) was added methyl iodide (11.6 mL, 0.17 mol). The mixture was heated to 68° C. and stirred for 48 hours. The precipitate thus formed was filtered, washed with THF (200 mL), and dried to afford the target compound (beige powder).

¹H-NMR (CDCl₃, 300 MHz, 5): 10.51 (s, 1H), 8.32 (d, J=9 Hz, 1H), 8.21 (m, 1H), 8.02 (d, J=9.0 Hz, 1H), 7.87 (m, 1H), 7.77 (m, 1H), 7.69 (m, 2H), 7.56 (m, 2H), 4.37 (s, 3H).

### [PREPARATION EXAMPLE 3] Synthesis of 1-(Dibenzo[b,d]thiophen-4-yl)-3-isopropyl-1H-imidazol-3-ium iodide (Compound 2b)

The same procedure was conducted, with the exception of using Compound 1 (6.0 g, 23.9 mmol), THF (100 mL), and isopropyl iodide (12.0 mL, 0.12 mol), to afford the target compound.

¹H-NMR (CDCl₃, 300 MHz, 6): 10.49 (s, 1H), 8.27 (d, J=8.2 Hz, 1H), 8.18 (m, 1H), 8.12 (d, J=7.3 Hz, 1H), 7.83 (m, 3H), 7.65 (t, J=7.8 Hz, 1H), 7.53 (m, 2H), 5.38 (spt, J=7.0 Hz, 1H), 1.77 (s, 3H), 1.74 (s, 3H).

### [SYNTHESIS EXAMPLES]—Synthesis of Ir Complex

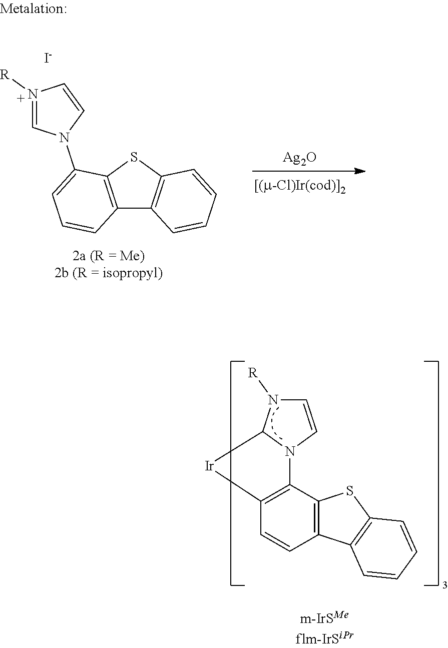

### [SYNTHESIS EXAMPLE 1] Synthesis of mer-Tris(N-dibenzothiophenyl-N′-methylimidazole)iridium(III) (m-IrS^{Me})

A solution of imidazolium salt (5.00 g, 12.75 mmol) synthesized in Preparation Example 2, iridium trichloride hydrate (1.12 g, 3.19 mmol), silver carbonate (1.76 g, 6.37 mmol), and sodium carbonate (0.67 g, 6.37 mmol) in 2-ethoxyethanol (50 mL) was refluxed for 16 hours. Then, the reaction mixture was cooled to room temperature and filtered. The filtrate was concentrated in a rotary evaporator. The residue was dissolved in CH₂Cl₂ (200 mL) and then added with water (50 mL). The organic phase was isolated by extraction before being dried over MgSO₄ and filtered. The filtrate was dried in a vacuum. The crude product was purified by silica gel column chromatography (R_{f}=0.8) using CH₂Cl₂/n-hexane (v/v=3/1) as an eluent, to afford the target compound.

¹H-NMR (DMSO-d₆, 600 MHz, δ): 8.14 (d, J=2.3 Hz, 1H), 8.10 (d, J=1.8 Hz, 1H), 8.04 (d, J=2.3 Hz, 1H), 7.99 (d, J=2.3 Hz, 1H), 7.97-7.91 (m, 3H), 7.61 (d, J=7.6 Hz, 1H), 7.54 (d, J=7.6 Hz, 1H), 7.50 (d, J=7.6 Hz, 1H), 7.46 (d, J=8.2 Hz, 1H), 7.42-?7.36 (m, H), 7.35 (d, J=2.3 Hz, 1H), 6.84 (d, J=7.6 Hz, 1H), 6.78 (d, J=7.6 Hz, 1H), 6.67 (d, J=7.6 Hz, 1H), 6.62 (d, J=8.2 Hz, 1H), 3.10 (s, 3H), 3.00 (s, 3H), 2.96 (s, 3H); ESI-MS calcd. for C₄₈H₃₃IrN₆S₃ (982.1558); found 982.1801 [M]⁺.

### [SYNTHESIS EXAMPLE 2] Synthesis of fac-Tris(N-dibenzothiophenyl-N′-isopropylimidazole)iridium (III) (f-IrS^{iPr}) and mer-Tris(N-dibenzothiophenyl-N′-isopropylimidazole)iridium (III) (m-IrS^{iPr})

The target compounds f-IrS^{iPr} and m-IrS^{iPr} were obtained in a manner similar to that of Synthesis Example 1. In this regard, use was made of the imidazolium salt (5.37 g, 12.8 mmol) synthesized in Preparation Example 3, iridium trichloride hydrate (1.12 g, 3.19 mmol), silver carbonate (1.76 g, 6.37 mmol), sodium carbonate (0.67 g, 6.37 mmol), and 2-ethoxyethanol (50 mL). The crude product was purified by column chromatography using CH₂Cl₂/n-hexane (v/v=2/1) as an eluent (R_{f}=0.5 for f-IrS^{iPr}; and R_{f}=0.7 for m-IrS^{iPr}), to afford the title compounds.

\textcircled{1} f-IrS^{iPr}. ¹H-NMR (DMSO-d₆, 600 MHz, δ): 8.10 (d, J=6.0 Hz, 3H), 8.07 (t, J=4.1 Hz, 3H), 7.95 (t, J=4.7 Hz, 3H), 7.55 (d, J=2.3 Hz, 3H), 7.47 (d, J=8.2 Hz, 9H), 7.41 (t, J=4.1 Hz, 3H), 6.57 (d, J=7.6 Hz, 3H), 3.96 (spt, J=6.7 Hz, 3H), 1.36 (d, J=7.03 Hz, 9H), 0.55 (d, J=6.4 Hz, 9H). ESI-MS calcd. for C₅₄H₄₅IrN₆S₃ (1066.2497); found 1066.2564 [M]⁺.

\textcircled{2} m-IrS^{iPr}. ¹H-NMR (DMSO-d₆, 600 MHz, δ): 8.17 (t, J=2.1 Hz, 2H), 8.12-8.06 (m, 2H), 8.04 (d, J=2.3 Hz, 1H), 8.03-8.01 (m, 1H), 7.96-7.91 (m, 3H), 7.62 (d, J=2.3 Hz, 1H), 7.58 (d, J=4.7 Hz, 1H), 7.57 (s, 1H), 7.56 (d, J=2.3 Hz, 1H), 7.52 (d, J=7.6 Hz, 1H), 7.42 (d, J=7.6 Hz, 1H), 7.41-7.36 (m, 6H), 6.84 (d, J=7.6 Hz, 1H), 6.75 (d, J=6.75 Hz, 1H), 6.65 (d, J=8.2 Hz, 1H), 4.06-3.96 (m, 3H), 1.45 (d, J=7 Hz, 3H), 1.09 (d, J=6.4 Hz, 3H), 1.05 (d, J=6.4 Hz, 3H), 0.61 (d, J=6.4 Hz, 3H), 0.45 (d, J=7 Hz, 3H), 0.42 (d, J=6.4 Hz, 3H); ESI-MS calcd. for C₅₄H₄₅IrN₆S₃ (1066. 2497); found 1066.2681 [M]⁺.

### EXPERIMENTAL EXAMPLE 1

### (1) Crystal Structures

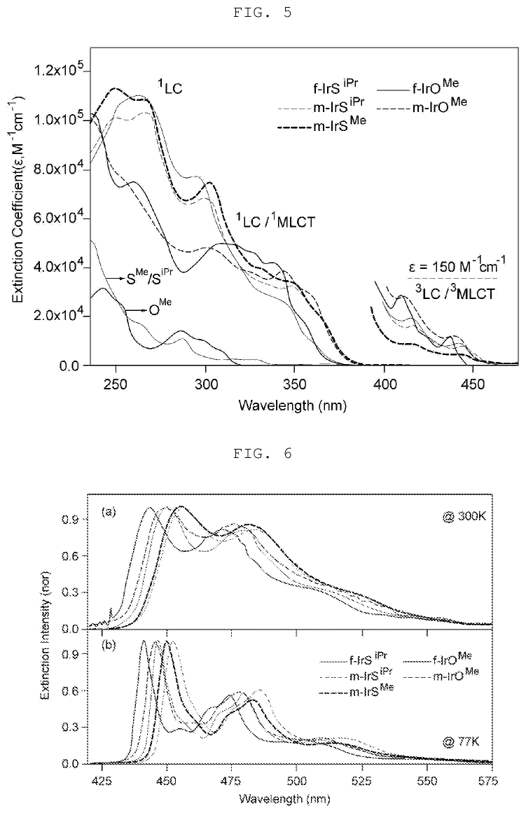

X-ray crystal structures of f-IrS^{iPr} and m-IrS^{iPr} synthesized in Synthesis Example 2 are depicted in FIG. 4, with the crystallographic data thereof given in Table 1. Slow vaporization of the dichloromethane (DCM)/n-hexane solution grew the single crystals. f-IrS^{iPr} and m-IrS^{iPr} were crystallized in the trigonal crystal system and triclinic system that possess the space groups P-3 and P-1 with final reliability factors (Rf) of 3.90% and 1.96%, respectively.

TABLE 1

| | | f-IrS^{iPr} | m-IrS^{iPr} | m-IrO^{Me} * |
|---|---|---|---|---|
| Bond | | Selected Bond Distances (Å) | | |
| Ir-Cᵢₘ | Ir-C1 | 2.042(5) | 2.067(2) | 2.068(5) |
| | Ir-C3 | | 2.044(2) | 2.044(6) |
| | Ir-C5 | | 2.026(2) | 2.036(5) |
| Ir-C_{Ph} | Ir-C2 | 2.087(4) | 2.099(2) | 2.118(6) |
| | Ir-C4 | | 2.089(2) | 2.090(6) |
| | Ir-C6 | | 2.066(2) | 2.092(5) |

As illustrated in FIG. 4, both the facial isomer and the meridional isomer possessed a quasi-octahedral coordination geometric structure around the metal. The f-IrSiPr complex was positioned on the threefold axis, resulting in very similar bond lengths between Ir—Cᵢₘ (Ir—C_{imidazolyl}) and Ir—Cₚₕ (Ir—C_{phenyl}), which were 2.042 (5) Å and 2.087(4) Å, respectively (see Table 1). Consistent with the σ-donation of the imidazolyl moiety in the transoid position, the Ir—Cᵢₘ bond length was shorter than the Ir—Cₚₕ bond length. As for the meridional isomer (m-IrS^{iPr}), its structural parameters were compared with those of m-IrO^{Me}. The Ir coordination environment of m-IrS^{iPr} was similar to that of m-IrO^{Me}. However, the bond length of Ir—Cₚₕ trans to the imidazolyl moiety in m-IrS^{iPr} (Ir—C6, 2.066(2) Å) was shorter than that in m-IrO^{Me} (2.092(5) Å), indicating that m-IrS^{iPr} and m-IrO^{Me} might exhibit slightly different photophysical properties. Furthermore, as seen in Table 1, the Ir—Cₚₕ bond lengths (C2 and C4) in the transoid position were significantly longer compared to Ir—C6. In contrast, the Ir—Cᵢₘ bond lengths (C3 and C5) were shorter than the bond length of Ir—C1. This implies that the Ir—C3 and Ir—C5 bonds had strong σ-donation to the iridium metal and due to the repulsion of these two strong donor groups, the bond lengths of Ir—C2 and Ir—C4 were elongated. Consequently, the meridional isomer had a much more distorted structure than the facial isomer.

### (2) Photophysical Properties

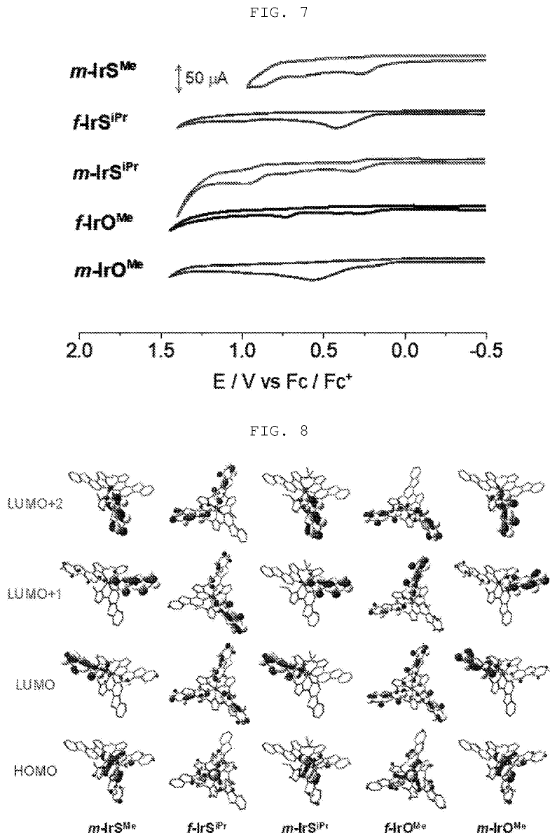

All absorption spectra of the iridium complexes and free ligands were recorded in DCM solution. Spectra and summarized data are illustrated in FIG. 5. For the free ligands, the dibenzothiophene derivatives (hereafter referred to as “S ligand” (S^{Me} and S^{iPr} analogues) exhibited strong high-energy bands at 240 nm and 280 nm, designated as ¹π-π* transitions (¹A→¹Lₐ). In contrast, a weaker low-energy band around 325 nm was attributed to the n-π* transition (¹A→¹L_{b}). The dibenzofuran derivative (hereinafter referred to as “O ligand”) showed a similar pattern in two absorption bands, but the O ligand exhibited more blue-shifted n-π* transitions compared to the S ligand. The red-shfted peak of S ligand indicates that the O ligand has a stronger electronegativity than the S ligand. The absorption spectrum of the Ir(III) complex clearly reflected the characteristics of these ligands. The Ir(III) complex displayed a strong absorption band around 250 nm (ε≈11×10⁴ M⁻¹cm⁻¹), attributed to the spin-allowed ligand-centered (¹LC, ¹ππ*) transition of the cyclometalating ligand. A weaker band near 325 nm (ε<6.0×10⁴ M⁻¹ cm⁻¹) represented a combination of the ¹LC transition and the metal-to-ligand charge transfer (¹MLCT) transition. The low-energy absorption band close to 350 nm (ε=<4.0×10⁴ M⁻¹cm⁻¹) was due to the ¹MLCT transition. The faintest absorption band observed from 400-460 nm in concentrated solutions, which might be related to the ³LC transition (in the enlarged section of FIG. 5), was detectable due to the heavy-atom effect of the iridium core, enhancing the mixing with the MLCT state (³LC+³MLCT). When comparing the absorption bands of facial isomers, a slight redshift was observed in meridional isomers, suggesting that meridional isomers have a smaller energy gap, as will be discussed in the sections on electrochemical properties and DFT calculations.

In particular, upon photo-excitation at 355 nm, all the Ir(III) complexes exhibited intense blue luminescence in liquid CH₂Cl₂ solution at 300 K (see FIG. 6(a)). The maximum luminescence, quantum efficiency, and lifetime of the Ir(III) complexes are summarized in Tables 2-4.

TABLE 2

| | 300 K^{a} | | | | |
|---|---|---|---|---|---|
| | Em, λₘₐₓ | Φₑₘ | τₑₘ | kᵣ | kₙᵣ |
| | (nm) | (%)^{b} | (μs) | (10⁴ s⁻¹) | (10⁴ s⁻¹) |
| m-IrS^{Me} | 455, 481 | 44.0 | 6.40 | 6.87 | 8.75 |
| f-IrS^{iPr} | 450, 478 | 58.1 | 7.24 | 8.02 | 5.79 |
| m-IrS^{iPr} | 456, 483 | 50.7 | 5.59 | 9.07 | 8.82 |
| f-IrO^{Me} | 444, 472 | 58.4 | 11.2 | 5.21 | 3.71 |
| m-IrO^{Me} | 450, 477 | 47.9 | 11.0 | 4.35 | 4.74 |

TABLE 3

| | film^{c} | | | | |
|---|---|---|---|---|---|
| | Em, λₘₐₓ | Φₑₘ | τₑₘ | kᵣ | kₙᵣ |
| | (nm) | (%)^{b} | (μs) | (10⁴ s⁻¹) | (10⁴ s⁻¹) |
| m-IrS^{Me} | 454, 481 | 72.7 | 15.02 | 4.84 | 1.82 |
| f-IrS^{iPr} | 449, 478 | 75.3 | 19.21 | 3.92 | 1.29 |
| m-IrS^{iPr} | 454, 482 | 75.7 | 18.58 | 4.07 | 1.31 |
| f-IrO^{Me} | 444, 472 | 70.6 | 15.19 | 4.65 | 1.94 |
| m-IrO^{Me} | 448, 476 | 73.5 | 16.05 | 4.58 | 1.65 |

TABLE 4

| | |
|---|---|
| At 77 K^{d} | Energy |

| | Em, λₘₐₓ | τₑₘ | | E_{g}^{f} | E_{T}^{g} |
|---|---|---|---|---|---|
| | (nm) | (μs) | S_{M}^{e} | (ev) | (eV) |
| m-IrS^{Me} | 450, 483 | 27.0 | 0.53 | 3.26 | 2.76 |
| f-IrS^{iPr} | 447, 480 | 30.5 | 0.61 | 3.33 | 2.78 |
| m-IrS^{iPr} | 452, 485 | 25.5 | 0.57 | 3.27 | 2.75 |
| f-IrO^{Me} | 441, 474 | 20.7 | 0.56 | 3.38 | 2.81 |
| m-IrO^{Me} | 446, 478 | 23.7 | 0.59 | 3.29 | 2.78 |

The Ir—S complexes (f-IrS^{iPr}, m-IrS^{iPr}, and m-IrS^{Me}) exhibited blue luminescence with peaks at 450, 456, and 455 nm, respectively. The meridional isomer, m-IrS^{iPr}, showed slightly red-shifted luminescence compared to the facial isomer, f-IrS^{iPr}. A similar phenomenon was observed in Ir—O complexes with f-IrO^{Me} at 444 nm and m-IrO^{Me} at 450 nm. These findings are consistent with the relatively long absorption edge of the meridional isomers and thus the lower energy band gaps for these meridional isomers (see the energies (E_{g}, E_{T}) in Table 4). Additionally, although the m-IrS^{Me} complex has the same molecular skeleton as the m-IrO^{Me} complex, it exhibited a slightly red-shifted luminescence (−5 nm) compared to m-IrO^{Me}. This is likely due to the S atom being more polarizable than the O atom, resulting in an enhanced conjugate effect from the dibenzothiophene (DBT) ligand. This implies that the excited state of DBT-based Ir complexes was more stable than that of dibenzofuran complexes.

The emission from Ir complexes undergoes a rigidochromic shift at low temperature (77 K). This shift is small (3-5 nm) compared to that of other NHC—Ir (III) complexes, including rigidochromic shifts of 45 for fac-Ir(pmp)₃, 65 nm for mer-Ir(pmp)₃ and 11 nm for Ir(pmi)₃ at low temperature. Unlike other meridional analogues, where the emission structure is broadened and the solvatochromic shift increases to 20-50 nm depending on the polarity of the solvent, these meridional isomers maintain their emission structures and exhibit a solvatochromic shift as small as 7 nm. These small rigidochromic and solvatochromic shifts indicate that the dipole moment change of Ir(III) complexes is very small and there is no drastic change in geometry in the excited state. The Huang-Rhys factor (S_{M}), which was estimated from the emission peak intensity ratio of the first and second features at 77 K, can serve as a useful parameter representing the degree of structural distortion in the excited state compared to the ground state. It is difficult to draw conclusions about the differences between the Ir complexes because the variation in S_{M} of the IrS and IrO complexes is not significant enough (S_{M}=0.53-0.61). However, the S_{M} of these Ir(III) complexes was considerably less than the value obtained for Ir(pmi)₃ (S_{M}=0.90). This implies that the DBF and DBT-substituted complexes have excited-state geometries that are less distorted relative to their ground state when compared to Ir(pmi)₃. This structural rigidity leads to a greater improvement in the emission quantum efficiency of iridium complexes (Φₑₘ: 44.0-58.4%) compared to Ir(pmi) 3 (Φₑₘ<5% in 2-MeTHF solution at room temperature) as shown in Table 2. In solution, the meridional isomers have lower emission quantum efficiency and shorter emission decay lifetimes than the facial isomers. In addition, the non-radiative rate constant (kₙᵣ) obtained using these relationships was greater for the meridional isomers than the facial isomers (relationship: τ_{rad}=τₑₘ/Φₑₘ, kᵣ=1/τ_{rad}, Φₑₘ=kᵣ/(kᵣ+kₙᵣ), and τₑₘ=1/(kᵣ+kₙᵣ)). These non-radiative processes may involve geometric distortion in the excited state. The film samples of Ir dopants were prepared by diluting the Ir complexes in PMMA (10 wt %), which is the same doping concentration equivalent to 10 wt % Ir used in the light emitting layer of the device. In this regard, PMMA polymer is used as the matrix instead of host material (TSP01) in order to measure only the photophysical properties of the Ir complex from Ir-doped film. The PL wavelengths in the films are almost similar to those in the diluted solution (see Tables 2 to 4), indicating that there are no aggregation and intermolecular interactions in the Ir-doped PMMA film. Compared to the emission quantum yields (Φₑₘ) in diluted solution, the highly enhanced solid-state emission efficiencies of Ir dopants can be interpreted in terms of the restricted motion of Ir complex in rigid solid media, which is characterized as the decreased non-radiative decay rate constants (kₙᵣ=1.3×10⁴−1.9×10⁴ s⁻¹), 2-7 fold lower than that in solution (kₙᵣ=3.7×10⁴−8.8×10⁴ s⁻¹). This film behavior is predicted to be particularly relevant to the use of these Ir complexes as phosphorescent dopants in applications such as OLEDs.

### (3) Electrochemical Properties

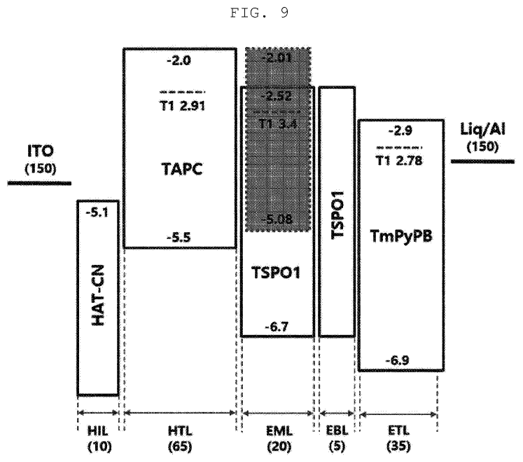

The redox behavior of the Ir(III) complexes was investigated using cyclic voltammetry (CV) in anhydrous dimethylformamide (DMF) solution under argon atmosphere. The CV was performed using a three-electrode cell system: a platinum disk electrode was used as the working electrode and a platinum wire and Ag/AgNO₃ were used as the counter and reference electrodes, respectively. As shown in FIG. 7, all of the complexes show irreversible oxidation potentials of 0.13, 0.06, 0.17, 0.14, and 0.11 V for f-IrO^{Me}, m-IrO^{Me}, f-IrS^{iPr}, m-IrS^{iPr}, and m-IrS^{Me}, respectively. The oxidation potentials of the Ir complexes with DBT (f-IrS^{iPr}, m-IrS^{iPr}) were slightly stabilized by 0.04-0.08 eV compared to their DBF analogues (f-IrO^{Me}, m-IrO^{Me}), but the difference is negligible. The ionization potentials (IPs) were estimated by the onset of the oxidation potentials taking ferrocene as the reference level (4.8 eV below the vacuum level): IP (eV)=−e(Eₒₙₛₑₜ^{ox}+4.8). Since no reduction wave was detected in these complexes due to the restricted range available in solution, the electron affinities (EAs) of the iridium complexes were determined through their IPs and absorption edge energies: EA (eV)=e(IP−E_{g}). The EA values were calculated as −1.56, −1.58, −1.65, −1.68, and −1.64 eV for f-IrO^{Me}, m-IrO^{Me}, f-IrS^{iPr}, m-IrS^{iPr}, and m-IrS^{Me}, respectively. Furthermore, the oxidation potentials shift toward the oxidative direction in the facial isomer, while the EA levels in the meridional isomers are only slightly less negative than those of the facial isomers.

### (4) DFT Calculations

To better understand the relationship between the structural and photophysical properties of the compounds, the structures of the Ir complexes were optimized using the DFT method (Density Functional Theory method) with the B3LYP/LANL2DZ basis set level. For the optimized geometries, the molecular coordination obtained by X-ray crystallography was used.

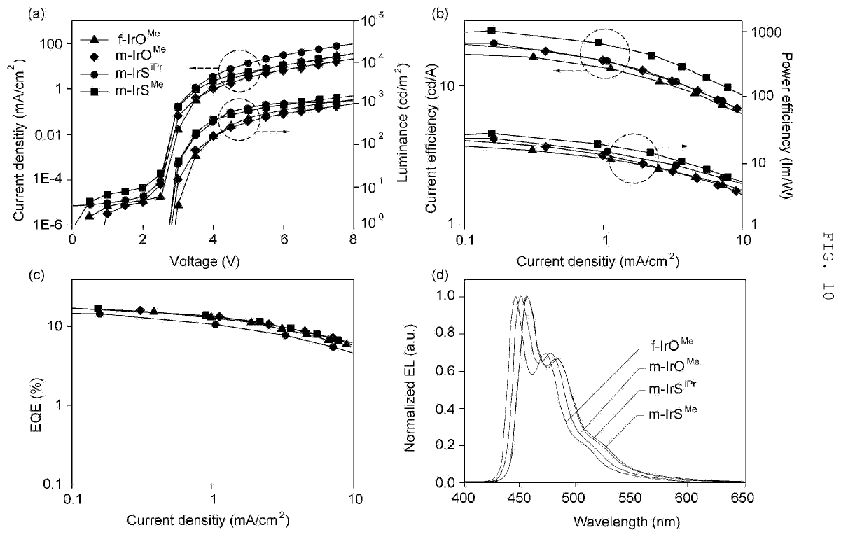

Time-dependent DFT (TD-DFT) calculations with the same functional and basis set show that the T₁ state of the lower-lying transitions is mainly associated with the highest occupied molecular orbital (HOMO)→the lowest unoccupied molecular orbital (LUMO), HOMO→LUMO+1, or HOMO→LUMO+2 transition, which represent a mix of LLCT and MLCT. The calculated wavelengths of the S₀→T₁ transitions align well with the experimentally observed absorption spectra. FIG. 8 shows the optimized molecular structures and the MO distribution of HOMO, LUMO, LUMO+1, and LUMO+2. For all complexes, the molecular orbital analysis indicated that the HOMO orbital is localized on the iridium atom (23-39%) and the aryl part (imidazole+DBT or DBF; 51-60%), with the DBT or DBF portion that is directly linked to the iridium atom providing the major contribution. The LUMO orbitals spread from the DBT or DBF part (77-89%). Moreover, for the facial isomer, the HOMO and LUMO orbitals are equally populated between the ligands due to their configuration, which sits on a three-fold axis. However, for meridional isomer, the HOMO orbital is localized to the metal and transoid ligand rather than the other ligands, and the shape of the LUMO orbital is nearly identical to that of LUMO+1 and LUMO+2. These orbitals are alternatively located on the DBT or DBF ligand. Replacing the DBF moiety with a DBT group affects the energy level of the Ir complexes, but the difference is a practically negligible 0.08 eV (HOMO energy level: −4.75 eV for m-IrS^{Me}; and −4.67 eV for m-IrO^{Me}). Differences in energy levels between meridional isomers and facial isomers account for other more important matter. The HOMO and LUMO levels (ca. 0.10 eV) of the meridional isomers are less stable than those of the facial isomers. To elucidate the nature of the excited triplet state, geometrical optimization of the Ir complexes was performed. The highest singly occupied molecular orbitals (HSOMOs) and the lowest singly occupied molecular orbitals (LSOMOs) of the Ir complexes are similar to the LUMO and HOMO orbitals in the S₀ state, respectively, except for the HSOMOs of the facial isomers (f-IrS^{iPr} and f-IrO^{Me}) The distribution of HSOMO of f-IrS^{iPr} differed from that of LUMO, which may be due to the molecular distortion in the excited triplet state. The HSOMO was localized to the DBT moiety, indicating that the excited DBT moiety significantly contributes to phosphorescence emission in the triplet state.

### EXAMPLE 1

A blue phosphorescent OLED was fabricated to have the structure of ITO (150 nm, anode)/HAT-CN (10 nm)/TAPC (65 nm)/TSPO1: m-IrS^{iPr} (20 nm: 10 wt %)/TSPO1 (5 nm)/TmPyPB (35 nm)/Liq (1 nm)/Al (150 nm, cathode), wherein the m-IrS^{iPr} synthesized in Synthesis Example 2 was employed as a dopant (FIG. 9). Use was made of HAT-CN (1,4,5,8,9,11-hexaazatriphenylene-hexacarbonitrile) for the hole injection layer (HIL), TAPC (4,4′-cyclohexylidene-bis[N,N-bis(4-methylphenyl)benzeneamine]) for the hole transport layer (HTL), TSPO1 (diphenyl-4-triphenylsilylphenylphosphine oxide) as a host, and TmPyPB (1,3,5-tri(m-pyridin-3-ylphenyl)benzene) for the electron transport layer (ETL). m-IrS^{iPr} has the following structure (iPr stands for isopropyl).

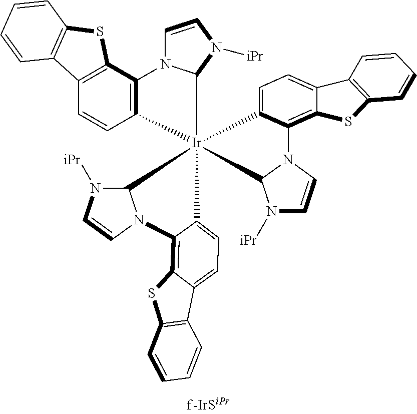

### EXAMPLE 2

A blue phosphorescent OLED was fabricated to have the structure of ITO (150 nm, anode)/HAT-CN (10 nm)/TAPC (65 nm)/TSPO1: m-IrS^{Me} (20 nm: 10 wt %)/TSPO1 (5 nm)/TmPyPB (35 nm)/Liq (1 nm)/Al (150 nm, cathode) wherein the m-IrS^{Me} synthesized in Synthesis Example 1 was employed as a dopant. The HAT-CN, TAPC, TSPO1, and TmPyPB were as described in Example 1. m-IrS^{Me} has the following structure (Me stands for methyl).

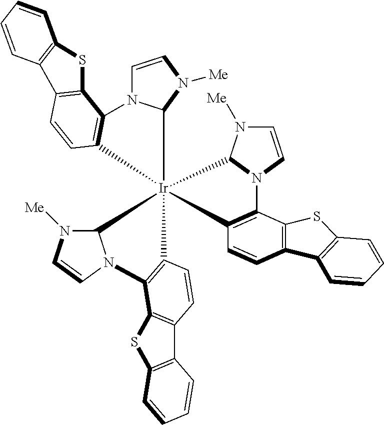

### COMPARATIVE EXAMPLE 1

A blue phosphorescent OLED was fabricated to have the structure of ITO (150 nm, anode)/HAT-CN (10 nm)/TAPC (65 nm)/TSPO1: f-IrO^{Me} (20 nm: 10 wt %)/TSPO1 (5 nm)/TmPyPB (35 nm)/Liq (1 nm)/Al (150 nm, cathode) wherein the following f-IrO^{Me} was employed as a dopant. In this regard, HAT-CN, TAPC, TSPO1, and TmPyPB were as described in Example 1. f-IrO^{Me} has the following structure (Me stands for methyl).

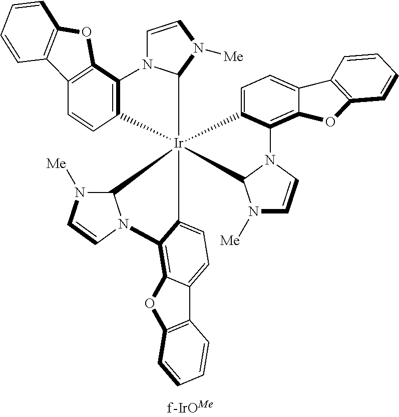

### COMPARATIVE EXAMPLE 2

A blue phosphorescent OLED was fabricated to have the structure of ITO (150 nm, anode)/HAT-CN (10 nm)/TAPC (65 nm)/TSPO1: m-IrO^{Me} (20 nm: 10 wt %)/TSPO1 (5 nm)/TmPyPB (35 nm)/Liq (1 nm)/Al (150 nm, cathode) wherein the following m-IrO^{Me} was employed as a dopant. In this regard, HAT-CN, TAPC, TSPO1, and TmPyPB were as described in Example 1. m-IrO^{Me} has the following structure (Me stands for methyl).

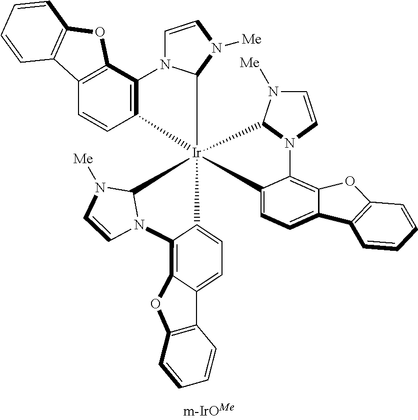

### EXPERIMENTAL EXAMPLE 1

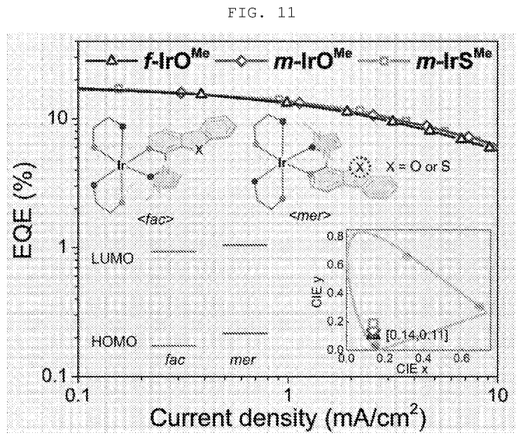

Blue phosphorescent OLEDs of Examples 1-2 and Comparative Examples 1-2 were measured for J-V-L characteristics, current efficiency-current density-power efficiency, external quantum efficiency, and electroluminescence spectrum, and the results are summarized in Table 5, below, and depicted in FIGS. 10 and 11. In this regard, current efficiency (η_{c}), power efficiency (ηₚ), external quantum efficiency (hereinafter referred to as “EQE”) (ηₑₓₜ) were the maximum values of each device. The efficiency roll-off was calculated as the ratio of the maximum EQE to the EQE at 100 mA/cm².

TABLE 5

| | | | | | | | | Roll- | |
|---|---|---|---|---|---|---|---|---|---|
| | | λₘₐₓ | FWHM | η_{c} | ηₚ | Vₒₙ | ηₑₓₜ | off | CIE |
| | Dopant | (nm) | (nm) | (cd/A)^{a} | (lm/W)^{a} | (V) | (%)^{a} | (%)^{b} | (x, y) |
| Example 1 | m-IrS^{Me} | 457 | 47 | 24.8 | 26.3 | 2.75 | 17.1 | 64.6 | (0.14, 0.10) |
| Example 2 | m-IrS^{iPr} | 457 | 47 | 20.9 | 25.0 | 2.75 | 16.7 | 70.6 | (0.14, 0.17) |
| Comparative | f-IrO^{Me} | 446 | 44 | 18.6 | 19.4 | 2.60 | 18.5 | 66.2 | (0.14, 0.11) |
| Example 1 | | | | | | | | | |
| Comparative | m-IrO^{Me} | 451 | 46 | 18.8 | 23.6 | 2.50 | 18.2 | 68.2 | (0.14, 0.14) |
| Example 2 | | | | | | | | | |

As can be understood from the data of Table 5, the devices of Examples 1-2 exhibited slightly higher maximum current efficiencies and power efficiencies, compared to those of Comparative Examples 1-2.

Meanwhile, the devices of Comparative Examples 1-2 outperformed those of Examples 1-2 in terms of EQE. This difference could be understood from the fact that EQE in solution and films is relatively higher for m-IrO^{Me} (Φₑₘ=47.9% and 73.5%) than for m-IrS^{Me} (Φₑₘ=44.0% and 72.7%).

However, at high current density (100 mA/cm²), all the devices of Examples 1-2 and Comparative Examples 1-2 exhibit efficiency roll-off in the range of 64% to 68% (FIG. 10). This phenomenon is considered to be caused by the non-radiative triplet exciton quenching pathway including triplet-triplet annihilation (TTA) in the emissive layer. The EL emission spectra of all devices, which are more well-structured than in solution at 300 K, are positioned around 452 nm with narrow full-width-at-half-maximum (FWHM) of 44-47 nm (FIG. 10d). The overall spectral features are consistent with the steady-state emission properties of the Ir(III) complexes, indicating that the EL emissions originate from Ir dopants in the emitting layer

In addition, as can be seen in Table 5 and FIG. 11, the device of Example 2 including m-IrS^{Me} (EQEₘₐₓ; 17.1%) had CIE coordinates of [0.14, 0.19] while the device of Comparative Example 2 including m-IrO^{Me} (EQEₘₐₓ; 18.2%) had CIE coordinates of [0.14, 0.14]. Here, m-IrS^{Me} and m-IrO^{Me} are dibenzothiophene (DBT)- and dibenzofuran (DBF)-based NHC—Ir complexes, respectively, demonstrating that their application to OLEDs achieve deep-blue emission.

1. An iridium complex represented by the following Chemical Formula 1: 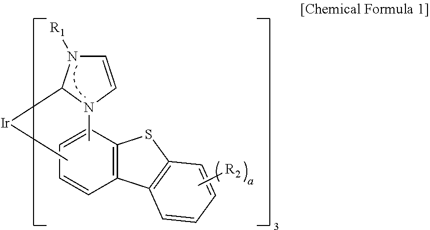
(wherein,
R₁ is an alkyl of C₁-C₂₀,
a is an integer of 0 to 4,
R₂ is selected from the group consisting of a hydrogen atom, a deuterium atom, a halogen, a cyano, an alkyl of C₁-C₂₀, an alkenyl of C₂-C₄₀, an alkynyl of C₂-C₂₀, a cycloalkyl of C₃-C₂₀, a heterocycloalkyl of 3 to 20 nuclear atoms, an aryl of C₆-C₂₀, a heteroaryl of 5 to 20 nuclear atoms, an alkyloxy of C₁-C₂₀, and an aryloxy of C₆-C₂₀).

2. The iridium complex of claim 1, wherein the iridium complex represented by Chemical Formula 1 is an iridium complex represented by Chemical Formula 2: 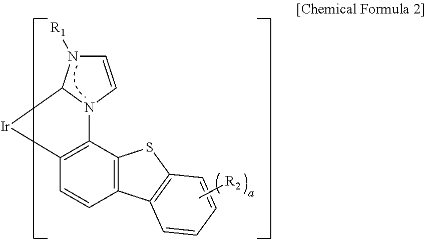
(wherein
R₁, R₂, and a are as defined in claim 1).

3. The iridium complex of claim 1, wherein the iridium represented by Chemical Formula 1 is represented by any one of the following Chemical Formulas 3 to 5: 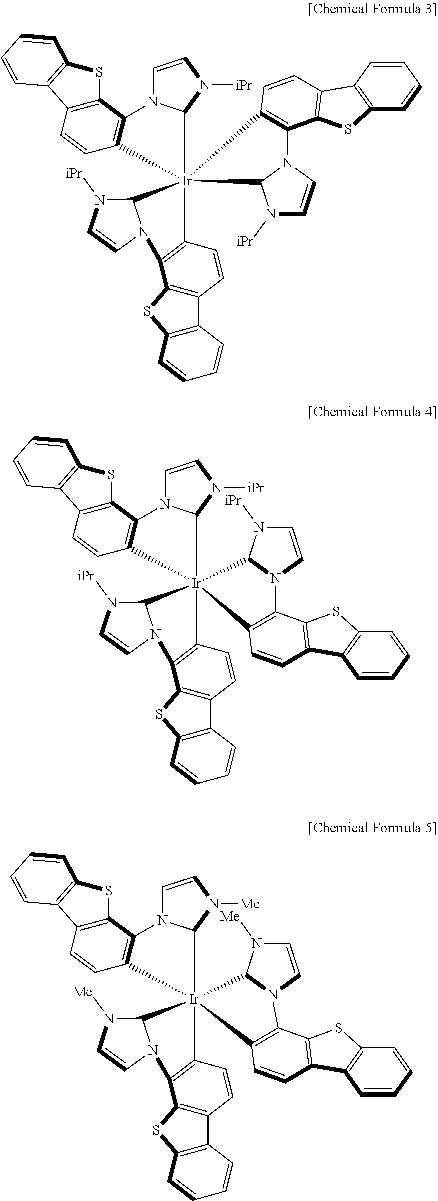
(wherein,
iPr is isopropyl, and
Me is methyl).

4. An electroluminescent device, comprising:
an anode; a cathode; and one or more organic layers disposed between the anode and the cathode,
wherein at least one of the one or more organic layers comprises the iridium complex of any one of claims 1 to 3.

5. The electroluminescent device of claim 4, wherein the one or more organic layers comprise a light-emitting layer, the light-emitting layer containing the iridium complex.

6. The electroluminescent device of claim 5, wherein the iridium complex is used as a blue phosphorescent dopant.
